(19) United States
(12) Patent Application Publication
(10) Pub. No.: US 2019/0169212 A1
(43) Pub. Date: Jun. 6, 2019

(54) AMINOCHLOROHYDRIDODISILANES

(71) Applicant: Dow Silicones Corporation, Midland, MI (US)

(72) Inventors: Noel CHANG, Midland, MI (US); Byung K. HWANG, Midland, MI (US); Brian David REKKEN, Midland, MI (US); Xiaobing ZHOU, Midland, MI (US)

(21) Appl. No.: 16/300,201

(22) PCT Filed: May 15, 2017
(86) PCT No.: PCT/US2017/032619

§ 371 Date: Nov. 9, 2018

Related U.S. Application Data
(60) Provisional application No. 62/337,371, filed on May 17, 2016.
(60) Provisional application No. 62/439,236, filed on Dec. 27, 2016.

(51) Int. Cl. C07F 7/10; C23C 16/34; C23C 16/40; C23C 16/50; C23C 16/455; H01L 21/02

(52) U.S. Cl. CPC C07F 7/10; C23C 16/345; C23C 16/402; C23C 16/50; C23C 16/45553; C23C 16/45536; H01L 21/0214; H01L 21/02167; H01L 21/0217; H01L 21/02164; H01L 21/02208; H01L 21/02271; H01L 21/0262; H01L 21/02532

(57) ABSTRACT

Disclosed is a Silicon Precursor Compound for deposition, the Silicon Precursor Compound comprising a compound which is a disilane and which comprises at least one chloro group, at least one dialkylamino group and at least one hydrido group. A composition for film forming is also disclosed, the composition comprising the Silicon Precursor Compound and at least one of an inert gas, molecular hydrogen, a carbon precursor, a nitrogen precursor, and an oxygen precursor. Further disclosed is a process of synthesizing the Silicon Precursor Compound; a method of forming a silicon-containing film on a substrate using the Silicon Precursor Compound; the silicon-containing film formed thereby; and a method of forming the Silicon Precursor Compound.

The present invention generally relates to a precursor compound and composition for film forming, to a process of synthesizing the precursor compound, to a method for forming a film with the precursor compound or composition via a deposition apparatus, and to the film formed by the method.

Elemental silicon, and other silicon materials such as silicon oxide, silicon carbide, silicon nitride, silicon carbonitride, and silicon oxycarbonitride, have a variety of known uses. For example, silicon film may be used as a semiconductor, an insulating layer or a sacrificial layer in the manufacture of electronic circuitry for electronic or photovoltaic devices.

Known methods of preparing the silicon material may use one or more silicon precursors. Use of these silicon precursors is not limited to making silicon for electronic or photovoltaic semiconductor applications. For example, silicon precursors may be used to prepare silicon-based lubricants, elastomers, and resins.

We see a long-felt need in the electronics and photovoltaic industries for improved silicon precursors. We think improved precursors would enable lowering of deposition temperatures and/or making finer semiconductor features for better performing electronic and photovoltaic devices.

### SUMMARY OF THE INVENTION

We have discovered an improved silicon precursor. The present invention provides each of the following embodiments:

A precursor compound for deposition, the precursor compound comprising a compound which is a disilane and which comprises at least one chloro group, at least one dialkylamino group and at least one hydrido group (hereinafter, “Silicon Precursor Compound”).

A composition for film forming, the composition comprising the Silicon Precursor Compound and at least one of an inert gas, molecular hydrogen, a carbon precursor, nitrogen precursor, and oxygen precursor.

A process of synthesizing the Silicon Precursor Compound, the method comprising contacting a disilane having at least two chloro groups and at least one dialkylamino group with an aluminum hydride.

A method of forming a silicon-containing film on a substrate, the method comprising subjecting a vapor of a silicon precursor comprising the Silicon Precursor Compound to deposition conditions in the presence of the substrate so as to form a silicon-containing film on the substrate.

A film formed in accordance with the method.

### DETAILED DESCRIPTION OF THE INVENTION

The Brief Summary and Abstract are incorporated here by reference. The invention embodiments, uses and advantages summarized above are further described below.

Aspects of the invention are described herein using various common conventions. For example, all states of matter are determined at 25° C. and 101.3 kPa unless indicated otherwise. All % are by weight unless otherwise noted or indicated. All % values are, unless otherwise noted, based on total amount of all ingredients used to synthesize or make the composition, which adds up to 100%. Any Markush group comprising a genus and subgenus therein includes the subgenus in the genus, e.g., in “R is hydrocarbyl or alkenyl,” R may be alkenyl, alternatively R may be hydrocarbyl, which includes, among other subgenuses, alkenyl. For U.S. practice, all U.S. patent application publications and patents referenced herein, or a portion thereof if only the portion is referenced, are hereby incorporated herein by reference to the extent that incorporated subject matter does not conflict with the present description, which would control in any such conflict.

Aspects of the invention are described herein using various patent terms. For example, “alternatively” indicates a different and distinct embodiment. “Comparative example” means a non-invention experiment. “Comprises” and its variants (comprising, comprised of) are open ended. “Consists of” and its variants (consisting of) is closed ended. “Contacting” means bringing into physical contact. “May” confers a choice, not an imperative. “Optionally” means is absent, alternatively is present.

Aspects of the invention are described herein using various chemical terms. The meanings of said terms correspond to their definitions promulgated by IUPAC unless otherwise defined herein. For convenience, certain chemical terms are defined.

The term “deposition” is a process of generating, on a specific place, condensed matter. The condensed matter may or may not be restricted in dimension. Examples of deposition are film-forming, rod-forming, and particle-forming depositions.

The term “film” means a material that is restricted in one dimension. The restricted dimension may be characterized as “thickness” and as the dimension that, all other things being equal, increases with increasing length of time of a process of depositing said material to form the film.

The term “halogen” means fluorine, chlorine, bromine or iodine, unless otherwise defined.

The term “IUPAC” refers to the International Union of Pure and Applied Chemistry.

The term “lack” means free of or a complete absence of.

“Periodic Table of the Elements” means the version published 2011 by IUPAC.

The term “precursor” means a substance or molecule containing atoms of the indicated element and being useful as a source of that element in a film formed by a deposition method.

The term “separate” means to cause to physically move apart, and thus as a result is no longer in direct touching.

The term “substrate” means a physical support having at least one surface upon which another material may be hosted.

This invention provides the Silicon Precursor Compound and the composition for film forming. The Silicon Precursor Compound is particularly suitable for deposition process for forming silicon-containing films, although the Silicon Precursor Compound is not limited to such applications. For example, the Silicon Precursor Compound may be utilized in other applications, e.g. as a reactant for preparing siloxane or silazane materials. This invention further provides the method of forming a film and the film formed in accordance with the method.

The Silicon Precursor Compound is a disilane and which comprises at least one chloro group, at least one dialkylamino group and at least one hydrido group. When the Silicon Precursor Compound is used in the present composition and method, the Silicon Precursor Compound may have a purity of from 99 area % (GC) to 99.9999999 area % (GC). However, it is envisioned that the Silicon Precurson may have a purity of from 95 to 98% if used in non-electronics applications.

In one embodiment the Silicon Precursor compound has the formula (I): (R¹R²N)ₐCl_{b}H_{c}SiSiH_{d}Clₑ(R¹R²N)_{f}, wherein each R¹ independently is H, (C₁-C₆)alkyl, (C₃-C₆)cycloalkyl, (C₂-C₆)alkenyl, (C₂-C₆)alkynyl, or phenyl; and each R² independently is (C₁-C₆)alkyl, (C₃-C₆)cycloalkyl, (C₂-C₆)alkenyl, (C₂-C₆)alkynyl, or phenyl; or R¹ and R² on a same or different nitrogen atom are bonded together to be —R^{1a}-R^{2a}— wherein —R^{1a}-R^{2a}— is (C₂-C₅)alkylene; and wherein a, b, c, d, e and f are integers which range independently from zero to three; provided that at least one of a and f is not zero, at least one of b and e is not zero and at least one of c and d is not zero.

In some aspects of the Silicon Precursor Compound, in formula (I) each R¹ and R² independently is (C₁-C₆)alkyl; alternatively R¹ is (C₁-C₆)alkyl and R² is (C₃-C₅)alkyl; alternatively R¹ is methyl or ethyl and R² is isopropyl, sec-butyl, iso-butyl, or tert-butyl; or each R¹ and R² independently is isopropyl, sec-butyl, iso-butyl, or tert-butyl; alternatively R¹ is methyl and R² is tert-butyl; alternatively each R¹ and R² independently is (C₃-C₄)alkyl; alternatively each R¹ and R² is isopropyl; alternatively each R¹ and R² is sec-butyl; alternatively R¹ is (C₃-C₆)cycloalkyl; alternatively R¹ is (C₂-C₆)alkenyl or (C₂-C₆)alkynyl; alternatively R¹ is H; alternatively R¹ is phenyl; alternatively and R¹ is as defined in any one of the immediately foregoing four aspects and R² is (C₁-C₆)alkyl or R² is the same as R¹; alternatively R¹ and R² are bonded together to be —R^{1a}-R^{2a}— wherein —R^{1a}-R^{2a}— is (C₃-C₅)alkylene; alternatively R¹ and R² on a same nitrogen are bonded together to be —R^{1a}-R^{2a}— wherein —R^{1a}-R^{2a}— is (C₄ or C₅)alkylene.

In some aspects of the Silicon Precursor Compound, in formula (I) only one of a and f is one, and the other is zero.

In some aspects of the Silicon Precursor Compound, in formula (I) b and e are independently zero, 1, or 2, alternatively 0, alternatively 1, alternatively 2, alternatively 3, alternatively 0 or 1, alternatively 1 or 2.

In some aspects of the Silicon Precursor Compound, in formula (I) b+e is from 1 to 4, alternatively 1, alternatively 2, alternatively 3, alternatively 4, alternatively from 2 to 4, alternatively from 3 or 4, alternatively 1 to 3, alternatively from 1 or 2, alternatively 2 or 3, alternatively 3 or 4.

In some aspects the Silicon Precursor Compound is [(CH₃)₂CH]₂NSiCl₂SiH₃, [(CH₃)₂CH]₂NSiH₂SiH₂Cl, [(CH₃CH₂)₂N]₂SiClSiH₃, [(CH₃CH₂)(CH₃)N]₂SiClSiH₃, HSiClN[CH(CH₃)₂]₂SiCl₃, HSiCl₂SiCl₂N[CH(CH₃)₂]₂, or HSiClN[CH(CH₃)₂]₂SiCl₂N[CH(CH₃)₂]₂ alternatively [(CH₃)₂CH]₂NSiCl₂SiH₃, [(CH₃)₂CH]₂NSiH₂SiH₂Cl, [(CH₃CH₂)₂N]₂SiClSiH₃ or [(CH₃CH₂)(CH₃)N]₂SiClSiH₃.

The Silicon Precursor Compound may be provided in any manner. For example, the Silicon Precursor Compound may by synthesized or otherwise obtained for use in the method. In an embodiment the Silicon Precursor Compound is synthesized by the following process. In a first step 2 HSiCl₃+heat->HSiCl₂SiCl₃+HCl, which may be separated therefrom such as via evaporation or stripping. In a (formal) second step, 2n HNR¹R²+HSiCl₂SiCl₃—>HSi₂(NR¹R²)ₙCl₅₋ₙ, wherein n is 1-4, and R¹, and R² are as defined above. When the source of the NR¹R² group(s) is HNR¹R², a reaction by-product, H₂NR¹R²Cl, is formed. When the source of the NR¹R² group(s) is M^{A}NR¹R², a reaction by-product, M^{A}(Cl)ₘ, is formed. The H₂NR¹R²Cl and M^{A}(Cl)ₘ salts may be separated therefrom such as via filtration or decantation. The second step of the process may comprise contacting, in a hydrocarbon vehicle, pentachlorodisilane (HSiCl₂SiCl₃) with a source of the NR¹R² group(s) to give the Silicon Precursor Compound; wherein the source of the NR¹R² group(s) is a metal R¹R²amide, [(R¹R²N]ₘM^{A}, wherein subscript m is 1 or 2, wherein when m is 1, M^{A} is an element of Group I of the Periodic Table of the Elements and when m is 2, M^{A} is an element of Group II of the Periodic Table of the Elements, or the source of the NR¹R² group(s) is HNR¹R².

The second step of the process of synthesizing the Silicon Precursor Compound may be carried out in a hydrocarbon vehicle or an ether vehicle. The ether vehicle may comprise a disilyl ether, a dihydrocarbyl ether, or an alkylene glycol dialkyl ether, or a mixture of any two or more thereof. The dihydrocarbyl ether may be a straight chain ether, a cyclic ether, or a diaryl ether, or a mixture of any two or more thereof. Examples of the ether vehicle are diethyl ether, dimethyl ether, tetrahydrofuran, 1,2-dimethoxyethane, tetraethylene glycol dimethyl ether. The alkylene glycol dialkyl ether may be a tetramethylene glycol di(C₁-C₄)alkyl ether, a propylene glycol di(C₂-C₄)alkyl ether, an ethylene glycol di(C₃ or C₄)alkyl ether, or a mixture of any two or more thereof. The hydrocarbon vehicle may comprise an alkane having at least 5 carbon atoms, a cycloalkane having at least 5 carbon atoms, an arene having at least 6 carbon atoms, or a mixture of any two or more thereof. The hydrocarbon vehicle may comprise a pentane, hexane, cyclohexane, heptane, benzene, toluene, xylene, or a mixture of any two or more thereof.

The composition of the hydrocarbon vehicle may be conceived to optimize the contacting steps (e.g., selecting a hydrocarbon vehicle having a boiling point for achieving a desired reaction temperature or a hydrocarbon vehicle lacking ability to solubilize a reaction by-product). Additionally or alternatively, the composition of the hydrocarbon vehicle may be conceived to optimize the optional separating step (e.g., selecting a hydrocarbon vehicle having a desired boiling point enabling evaporation thereof without evaporating the Silicon Precursor Compound). The hydrocarbon vehicle may consist of carbon and hydrogen atoms or may be a halogenated hydrocarbon vehicle consisting of carbon, hydrogen, and halogen atoms. The hydrocarbon vehicle consisting of C and H atoms may be alkanes, aromatic hydrocarbons, and mixtures of any two or more thereof. The alkanes may be hexanes, cyclohexane, heptanes, isoparaffins, or mixtures of any two or more thereof. The aromatic hydrocarbon may be toluene, xylenes, or mixtures of any two or more thereof. The halogenated hydrocarbon vehicle may be dichloromethane. The process having different compositions for hydrocarbon vehicle may differ from each other in at least one result, property, function, and/or use. Different compositions of the hydrocarbon vehicle may provide different solubilities for the Silicon Precursor Compound, the source of the NR¹R² group(s), a reaction by-product, or a combination of any two or more thereof.

The present invention is further directed to a method for producing a compound which is a disilane and which comprises at least one chloro group, at least one dialkylamino group and at least one hydrido group. The method comprises contacting a disilane having at least two chloro groups and at least one dialkylamino group with an aluminum hydride. Preferably, the disilane has only chloro groups and dialkylamino groups. An aluminum hydride is a compound having at least one hydrido group bound to an aluminum atom. Examples of aluminum hydrides include, e.g., diisobutyl aluminum hydride, diethyl aluminum hydride, lithium tri-tert-butoxyaluminum hydride, lithium tris[(3-ethyl-3-pentyl)oxy]aluminum hydride, sodium bis(2-methoxyethoxy)aluminum hydride, lithium aluminum hydride, sodium aluminum hydride and aluminum hydride. Preferred aluminum hydrides are diisobutyl aluminum hydride and diethyl aluminum hydride, preferably diisobutyl aluminum hydride. Preferably, the molar ratio of the disilane to the aluminum hydride is from 0.1:1 to 0:1, alternatively from 0.2:1 to 3.5:1, alternatively 0.3:1 to 3:1, alternatively 1:1 to 4:1, alternatively 1:1 to 3.5:1, alternatively 2:1 to 3:1. Preferably, the reaction temperature is from −30° C. to 40° C., alternatively from −30° C. to 20° C., alternatively from −25° C. to 15° C. Preferably, the reaction is carried out without a solvent.

As mentioned above, the composition for film forming comprises the Silicon Precursor Compound and at least one of an inert gas, molecular hydrogen, a carbon precursor, a nitrogen precursor, and an oxygen precursor. The molecular hydrogen may be used with the Silicon Precursor Compound in the composition for forming an elemental silicon film. A vaporous or gaseous state of the molecular hydrogen, carbon precursor, nitrogen precursor or oxygen precursor may be generally referred to herein as an additional reactant gas.

The carbon precursor may be used with the Silicon Precursor Compound in the composition for forming a silicon carbon film according to an embodiment of the method. The silicon carbon film contains Si and C atoms and may comprise silicon carbide. The carbon precursor may comprise, alternatively consist essentially of, alternatively consist of, C, H, and optionally Si atoms. The carbon precursor that comprises C, H, and optionally Si atoms may further comprise N or O atoms when the carbon precursor is used in the method for forming a silicon carbonitride film or silicon oxycarbide film, respectively, or may further comprise N and O atoms when the carbon precursor is used in the method for forming a silicon oxycarbonitride film. The carbon precursor that consists essentially of C, H, and optionally Si atoms lacks N and O atoms, but may optionally have one or more halogen atoms (e.g., Cl). Examples of the carbon precursor consisting of C and H atoms are hydrocarbons such as alkanes. Examples of the carbon precursor consisting of C, H and Si atoms are hydrocarbylsilanes such as butyldisilane or tetramethylsilane.

The nitrogen precursor may be used with the Silicon Precursor Compound in the composition for forming a silicon nitrogen film according to an embodiment of the method. The nitrogen precursor is different than the Silicon Precursor Compound. The silicon nitrogen film contains Si and N atoms and optionally C and/or O atoms and may comprise silicon nitride, silicon oxynitride, or silicon oxycarbonitride. The silicon nitride may be SiₓN_{y} wherein subscript x is 1, 2 or 3, alternatively an integer from 1 to 4, and subscript y is an integer from 1 to 5. The nitrogen precursor may comprise N atoms and optionally H atoms, alternatively the nitrogen precursor may consist essentially of N atoms and optionally H atoms, alternatively the nitrogen precursor may consist of N and optionally H atoms. The nitrogen precursor that comprises N and optionally H atoms may further comprise C or O atoms when the nitrogen precursor is used in the method for forming a silicon carbonitride film or silicon oxynitride film, respectively, or may further comprise C and O atoms when the nitrogen precursor is used in the method for forming a silicon oxycarbonitride film. The nitrogen precursor that consists essentially of N atoms and optionally H atoms lacks C and O atoms, but optionally may have one or more halogen atoms (e.g., Cl). An example of the nitrogen precursor consisting of N atoms is molecular nitrogen. Examples of the nitrogen precursor consisting of N and H atoms are ammonia and hydrazine. An example of the nitrogen precursor consisting of O and N atoms is nitric oxide (N₂O) and nitrogen dioxide (NO₂).

The oxygen precursor may be used with the Silicon Precursor Compound in the composition for forming a silicon oxygen film according to an embodiment of the method. The silicon oxygen film contains Si and O atoms and optionally C and/or N atoms and may comprise silicon oxide, silicon oxycarbide, silicon oxynitride, or silicon oxycarbonitride. The silicon oxide may be SiO or SiO₂. The oxygen precursor may comprise O atoms and optionally H atoms, alternatively may consist essentially of O atoms and optionally H atoms, alternatively may consist of O atoms and optionally H atoms. The oxygen precursor that comprises O atoms and optionally H atoms may further comprise C or N atoms when the oxygen precursor is used in the method for forming a silicon oxycarbide or silicon oxynitride film, respectively, or may further comprise C and N atoms when the oxygen precursor is used in the method for forming a silicon oxycarbonitride film. Examples of the oxygen precursor consisting of O atoms are molecular oxygen and ozone. Examples of the oxygen precursor consisting of O and H atoms are water and hydrogen peroxide. An example of the oxygen precursor consisting of O and N atoms is nitric oxide, nitrous oxide, and nitrogen dioxide.

The inert gas may be used in combination with any one of the foregoing precursors and any embodiment of the composition or method. Examples of the inert gas are helium, argon, and a mixture thereof. For example, helium may be used in combination with the Silicon Precursor Compound and molecular hydrogen in an embodiment of the method wherein the silicon containing film that is formed is an elemental silicon film. Alternatively, helium may be used with the Silicon Precursor Compound and any one of the carbon precursor, nitrogen precursor and oxygen precursor in an embodiment of the method wherein the silicon containing film that is formed is a silicon carbon film, silicon nitrogen film, or silicon oxygen film respectively.

The film formed by the method is a material containing Si and is restricted in one dimension, which may be referred to as thickness of the material. The silicon containing film may be an elemental silicon film, a silicon carbon film, a silicon nitrogen film, or a silicon oxygen film. (e.g., silicon oxide, silicon nitride, silicon carbonitride, silicon oxynitride, or silicon oxycarbonitride film. The elemental silicon film formed by the method lacks C, N and O atoms and may be an amorphous or crystalline Si material. The silicon carbon film formed by the method contains Si and C atoms and optionally N and/or O atoms. The silicon nitrogen film formed by the method contains Si and N atoms and optionally C and/or O atoms. The silicon oxygen film formed by the method contains Si and O atoms and optionally C and/or N atoms.

The film may be useful in electronics and photovoltaic applications. E.g., the silicon nitride film may be formed as an insulator layer, passivation layer, or a dielectric layer between polysilicon layers in capacitors.

The method of forming a film uses a deposition apparatus. The deposition apparatus utilized in the method is generally selected based upon the desired method of forming the film and may be any deposition apparatus known by those of skill in the art.

In certain embodiments, the deposition apparatus comprises a physical vapor deposition apparatus. In these embodiments, the deposition apparatus is typically selected from a sputtering apparatus, and a direct current (DC) magnetron sputtering apparatus. The optimum operating parameters of each of these physical deposition vapor apparatuses are based upon the Silicon Precursor Compound utilized in the method and the desired application in which the film formed via the deposition apparatus is utilized. In certain embodiments, the deposition apparatus comprises a sputtering apparatus. The sputtering apparatus may be, for example, an ion-beam sputtering apparatus, a reactive sputtering apparatus, or an ion-assisted sputtering apparatus.

More typically, however, the deposition apparatus comprises an atomic layer deposition apparatus or a chemical vapor deposition apparatus. In embodiments using the atomic layer deposition apparatus, the method of forming the film may be referred to as an atomic layer deposition method. Likewise in embodiments using the chemical vapor deposition apparatus, the method of forming the film may be referred to as a chemical vapor deposition method. Atomic layer deposition and chemical vapor deposition apparatuses and methods are generally well known in the art. The present method is exemplified below by reference to use of an atomic layer deposition apparatus, although the present method may be readily adapted for use with the chemical vapor deposition apparatus.

In embodiments of the method using the atomic layer deposition apparatus, the atomic layer deposition apparatus may be selected from, for example, a thermal atomic layer deposition apparatus, a plasma enhanced atomic layer deposition apparatus, and a spatial atomic layer deposition apparatus. The optimum operating parameters of each of these atomic layer deposition apparatuses are based upon the Silicon Precursor Compound utilized in the method and the desired application in which film formed via the deposition apparatus is utilized. One skilled in the art would know how to optimize the operating parameters of the particular apparatus employed.

In atomic layer deposition, gases for forming the film are typically introduced and reacted in a deposition chamber in a series of cycles, where a cycle comprises filling the reaction chamber with the Silicon Precursor Compound (first half reaction), purging the reactor with an inert gas, filling the reaction chamber with another reactive gas (second half reaction), and then purging the reactor with an inert gas. A series of cycles of the two half reactions (first and second) form the proper film elements or molecules on the substrate surface. Atomic layer deposition generally requires the addition of energy to the system, such as heating of the deposition chamber and substrate.

In embodiments of the method using the chemical vapor deposition apparatus, the chemical vapor deposition apparatus may be selected from, for example, a flowable chemical vapor deposition apparatus, a thermal chemical vapor deposition apparatus, a plasma enhanced chemical vapor deposition apparatus, a photochemical vapor deposition apparatus, an electron cyclotron resonance apparatus, an inductively coupled plasma apparatus, a magnetically confined plasma apparatus, a low pressure chemical vapor deposition apparatus and a jet vapor deposition apparatus. The optimum operating parameters of each of these chemical deposition vapor apparatuses are based upon the Silicon Precursor Compound utilized in the method and the desired application in which film formed via the deposition apparatus is utilized. In certain embodiments, the deposition apparatus comprises a plasma enhanced chemical vapor deposition apparatus. In other embodiments, the deposition apparatus comprises a low pressure chemical vapor deposition apparatus.

In chemical vapor deposition, gases for forming the film are typically mixed and reacted in a deposition chamber. The reaction forms the proper film elements or molecules in a vapor state. The elements or molecules then deposit on a substrate (or wafer) and build up to form the film. Chemical vapor deposition generally requires the addition of energy to the system, such as heating of the deposition chamber and substrate.

Reaction of gaseous species is generally well known in the art and any conventional chemical vapor deposition (CVD) technique can be carried out via the present method. For example, methods such as simple thermal vapor deposition, plasma enhanced chemical vapor deposition (PECVD), electron cyclotron resonance (ECRCVD), atmospheric pressure chemical vapor deposition (APCVD), low pressure chemical vapor deposition (LPCVD), ultrahigh vacuum chemical vapor deposition (UHVCVD), aerosol-assisted chemical vapor deposition (AACVD), direct liquid injection chemical vapor deposition (DLICVD), microwave plasma-assisted chemical vapor deposition (MPCVD), remote plasma-enhanced chemical vapor deposition (RPECVD), atomic layer chemical vapor deposition (ALCVD or ALD), hot wire chemical vapor deposition (HWCVD), hybrid physical-chemical vapor deposition (HPCVD), rapid thermal chemical vapor deposition (RTCVD), and vapor-phase epitaxy chemical vapor deposition (VPECVD), photo-assisted chemical vapor disposition (PACVD), flame assisted chemical vapor deposition (FACVD), or any similar technique may be used.

Chemical vapor deposition or atomic layer deposition may be utilized to form films having a wide variety of thicknesses contingent on a desired end use of the film. For instance, the film may have a thickness of a few nanometers or a thickness of a few microns, or a greater or lesser thickness (or a thickness falling between these values). These films may optionally be covered by coatings, such as SiO₂ coatings, SiO₂/modifying ceramic oxide layers, silicon-containing coatings, silicon carbon-containing coatings, silicon carbide-containing coatings, silicon nitrogen-containing coatings, silicon nitride-containing coatings, silicon nitrogen carbon-containing coatings, silicon oxygen nitrogen containing coatings, and/or diamond like carbon coatings. Such coatings and their methods of deposition are generally known in the art.

The substrate utilized in the method is not limited. In certain embodiments, the substrate is limited only by the need for thermal and chemical stability at the temperature and in the environment of the deposition chamber. Thus, the substrate can be, for example, glass, metal, plastic, ceramic, silicon (e.g. monocrystalline silicon, polycrystalline silicon, amorphous silicon, etc).

Embodiments of the present method may include a reactive environment comprising nitrous oxide (N₂O). Such reactive environments are generally known in the art. In these embodiments, the method generally involves decomposing the Silicon Precursor Compound in the presence of nitrous oxide. An example of such a method is described in U.S. Pat. No. 5,310,583. Utilizing nitrous oxide may modify the composition of the resulting film formed in the chemical vapor deposition method.

The chemical vapor deposition apparatus and atomic layer deposition apparatus and, thus, the chemical vapor deposition and atomic layer deposition methods utilized are generally selected by balancing a number of factors, including, but not limited to, the Silicon Precursor Compound, desired purity of the film, geometric configuration of the substrate, and economic considerations.

The main operating variables manipulated in chemical vapor deposition and atomic layer deposition include, but are not limited to, temperature, substrate temperature, pressure, a concentration in the gas phase of the Silicon Precursor Compound, any additional reactant gas concentration (e.g., concentration of gas of any carbon precursor, nitrogen precursor, and/or oxygen precursor), and total gas flow. Chemical vapor deposition or atomic layer deposition is generated from chemical reactions which include, but are limited to, pyrolysis, oxidation, reduction, hydrolysis, and combinations thereof. Selecting the optimal temperature for chemical vapor deposition or atomic layer deposition requires an understanding of both the kinetics and thermodynamics of the Silicon Precursor Compound and the chosen chemical reaction.

Conventional chemical vapor deposition methods generally require significantly high temperatures, such as greater than 600° C., e.g. 600° C. to 1000° C. However, it is believed that the Silicon Precursor Compound may be utilized in chemical vapor deposition or atomic layer deposition at much lower temperatures. For example, the method may be carried out at a temperature of from 25° C. to 700° C., alternatively from 100 to 700° C., alternatively from 200 C to 700° C., alternatively from 200 C to 600° C., alternatively from 200 C to 500° C., alternatively from 200 C to 400° C., alternatively from 100° C. to 300° C. The temperature at which the method is carried out may be isothermal or dynamic.

Chemical vapor deposition or atomic layer deposition processes generally involve generating a precursor, transporting the precursor into a reaction chamber, and either adsorption of precursors onto a heated substrate or chemical reaction of the precursor and subsequent adsorption onto the substrate. The following sets forth a cursory survey of chemical vapor deposition or atomic layer deposition methods to illustrate some of the vast options available.

In thermal CVD or ALD, the film is deposited by passing a stream of a vaporized form of the Silicon Precursor Compound over a heated substrate. When the vaporized form of the Silicon Precursor Compound contacts the heated substrate, the Silicon Precursor Compound generally reacts and/or decomposes to form the film.

In PECVD, a vaporized form of the Silicon Precursor Compound is reacted by passing it through a plasma field to form a reactive species. The reactive species is then focused and deposited on the substrate the form the film. Generally, an advantage of PECVD over thermal CVD is that lower substrate temperature can be used. The plasma utilized in PECVD comprise energy derived from a variety of sources such as electric discharges, electromagnetic fields in the radio-frequency or microwave range, lasers or particle beams. Generally, PECVD utilizes radio frequency (10 kilohertz (kHz)-102 megahertz (MHz)) or microwave energy (0.1-10 gigahertz (GHz)) at moderate power densities (0.1-5 watts per square centimeter (W/cm²)), although any of these variables may be modified. The specific frequency, power, and pressure, however, are generally tailored to the deposition apparatus.

In AACVD, the Silicon Precursor Compound is dissolved in a chemical medium to form a mixture. The mixture comprising the Silicon Precursor Compound and the chemical medium is packaged in a traditional aerosol. The aerosol atomizes and introduces the Silicon Precursor Compound into a heated chamber where the Silicon Precursor Compound undergoes decomposition and/or chemical reaction. One advantage of AACVD is the ability to form the film without necessitating a vacuum.

The chosen deposition process and operating parameters will have impact the structure and properties of the film. Generally, it is possible to control the orientation of film structure, the manner in which the film coalesces, the uniformity of the film, and crystalline/non-crystalline structure of the film.

It is to be noted that environments which facilitate the desired deposition can also be used in the deposition chamber. For instance, reactive environments such as air, oxygen, oxygen plasma, ammonia, amines, hydrazine, etc. or inert environments may all be used herein.

Additionally, the present invention provides a film formed in accordance with the method. The composition and structure of the film is a function of not only the deposition apparatus and its parameters, but also the Silicon Precursor Compound utilized and the presence or absence of any reactive environment during the method. The Silicon Precursor Compound may be utilized in combination with any other known precursor compounds or may be utilized in the method free from any other precursor compounds.

Because the Silicon Precursor Compound contains at least one Si—N bond, the Silicon Precursor Compound may be utilized to form silicon nitride films without use of a nitrogen precursor, although a nitrogen precursor may be also used if desired. That is, the addition of a nitrogen precursor (e.g., second vapor) may not be necessary to form a silicon nitride film. One may be able to optimize the deposition conditions to control whether the present method forms an elemental Si film or a SiN film. If desired the nitrogen precursor may be used in the second vapor to enrich the nitrogen content of the SiN film.

Alternatively, the Silicon Precursor Compound may be utilized with other silicon-based precursor compounds traditionally utilized to form silicon films comprising crystalline silicon or silicon nitride. In such embodiments, the films may be, for example, crystalline or epitaxial. Contingent on the presence of reactive environments during the method, the film may further comprise oxygen and/or carbon in addition to silicon and nitrogen.

Purity of the Silicon Precursor Compound may be determined by ²⁹Si-NMR, reverse phase liquid chromatography or, more likely, by gas chromatography (GC) as described later. For example, the purity determined by GC may be from 60 area % to ≤100 area % (GC), alternatively from 70 area % to ≤100 area % (GC), alternatively from 80 area % to ≤100 area % (GC), alternatively from 90 area % to ≤100 area % (GC), alternatively from 93 area % to ≤100 area % (GC), alternatively from 95 area % to ≤100 area % (GC), alternatively from 97 area % to ≤100 area % (GC), alternatively from 99.0 area % to ≤100 area % (GC). Each ≤100 area % (GC) independently may be as defined previously.

The invention is further illustrated by, and an invention embodiment may include any combinations of features and limitations of, the non-limiting examples thereof that follow. Ambient temperature is about 23° C. unless indicated otherwise.

Gas Chromatography-Flame Ionization Detector (GC-FID) conditions: a capillary column with 30 meters length, 0.32 mm inner diameter, and containing a 0.25 μm thick stationary phase in the form of a coating on the inner surface of the capillary column, wherein the stationary phase was composed of phenyl methyl siloxane. Carrier gas is helium gas used at a flow rate of 105 mL per minute. GC instrument is an Agilent model 7890A gas chromatograph. Inlet temperature is 200° C. GC experiment temperature profile consist of soaking (holding) at 50° C. for 2 minutes, ramping temperature up at a rate of 15° C./minute to 250° C., and then soaking (holding) at 250° C. for 10 minutes.

GC-MS instrument and conditions: Sample is analyzed by electron impact ionization and chemical ionization gas chromatography-mass spectrometry (EI GC-MS and CI GC-MS). Agilent 6890 GC conditions include a DB-1 column with 30 meters (m)×0.25 millimeter (mm)×0.50 micrometer (μm) film configuration, an inlet temperature of 200° C., an oven program of soaking at 50° C. for 2 minutes, ramping at 15° C./minute to 250° C., and soaking at 250° C. for 10 minutes. Helium carrier gas flowing at constant flow of at 1 mL/minute and a 50:1 split injection. Agilent 5973 MSD conditions include a MS scan range from 15 to 800 Daltons, an EI ionization and CI ionization using a custom CI gas mix of 5% NH₃ and 95% CH₄.

²⁹Si-NMR instrument and solvent: a Varian 400 MHz Mercury spectrometer is used. C₆D₆ is used as the solvent.

¹H-NMR instrument and solvent: a Varian 400 MHz Mercury spectrometer is used. C₆D₆ is used as the solvent.

Example 1. Synthesis of 1-Diisopropylamino-2-Chlorodisilane (DPDCH4)

In a 15 mL scintillation vial, 0.20 g (0.7 mmol) of 1,2-bis(diisopropylamine)disilane (BisDPDS) was diluted in 2 mL of pentane and stirred using a magnetic stir bar. 0.21 g (0.7 mmol) of hexachlorodisilane was added and stirred for 30 minutes. Analysis by GC-MS showed that nearly all of the BisDPDS was consumed to give the product DPDCH4 as the only major product (>90% conversion).

Example 2. Synthesis of Diisopropylaminotetrachlorodisilanes (DPDCH), Diisopropylaminotrichlorodisilanes (DPDCH2), and 1-Diisopropylamino-1,1-Dichlorodisilane (DPDCH3) in situ.

Diisopropylaminopentachlorodisilane (DPDC, 0.52 g, 1.6 mmol) was added to a 30-mL scintillation vial equipped with a magnetic stir bar. A thermocouple wire was sandwiched between the bottom of the vial and the top of the ceramic stir plate to monitor the reaction temperature. Diisobutylaluminum hydride (DiBAH, 0.23 g, 1.6 mmol) was added to the stirring DPDC dropwise where an exotherm was observed. The reaction mixture was analyzed using GC-FID and GC-MS to find the following composition: 2.00% (i-Pr₂N)SiCl₂H, 1.45% (i-Pr₂N)SiCl₃, 22.50% (i-Pr₂N)Si₂Cl₂H₃ (DPDCH3), trace (i-Pr₂N)Si₂Cl₃H₂ (DPDCH2), 3.15% (i-Pr₂N)Si₂Cl₄H (DPDCH), 68.83% (i-Pr₂N)Si₂Cl₅ (DPDC), and 2.07% other chlorosilanes.

Example 3. Synthesis of 1-Diisopropylamino-1,1-Dichlorodisilane (DPDCH3)

In the argon-filled glovebox, a 1-L jacketed round bottom flask equipped with a magnetic stirrer was charged with 66.8% pure diisopropylaminopentachlorodisilane (DPDC, 268.6 g, about 0.54 mol) and cooled to −15° C. Diisobutylaluminum hydride (DiBAH, 229.1 g, 1.61 mol) was added to the DPDC with rigorous stirring over the course of 3 hours in 30 g aliquots using a large plastic pipette to keep the reaction temperature under 10° C. At the end of the addition, the reaction mixture was returned to room temperature by raising the chiller setting in 10° C. increments (a second exotherm may be observed). Once the reaction mixture reached temperature, the content of the flask was transferred to a (non-jacketed) 1-L three-neck round bottom flask equipped with a thermocouple, a magnetic stir bar, and distillation column. The 80% crude 1-diisopropylamino-1,1-dichlorodisilane (DPDCH3) was isolated from high boiling byproducts by a strip distillation at full active vacuum at 74-82° C. pot temperature. Yield: 129.0 g (83.0%).

Example 4. Synthesis of Diisopropylaminotetrachlorodisilanes HSi₂(NPrⁱ₂)Cl₄ and Bis(diisopropylamino)trichlorodisilane HSi₂(NPrⁱ₂)₂Cl₃

To a 500 ml round-bottom flask was added 11.1 g (47.4 mmol) of pentachlorodisilane (PCDS) and 110 ml of anhydrous hexanes. The flask was cooled down to −10° C. in a dry ice-isopropanol bath. Under agitation, a solution containing 9.60 g (94.9 mmol) of diisopropylamine and 20 ml of anhydrous hexanes was added in 15 minutes at −10° C. A yellowish white slurry was formed. After the addition, the reaction mixture was warmed up to room temperature and continued to be agitated for 2 hours at room temperature. Then the slurry was filtered through a Type D glass frit covered with 0.5 inch thick dry Celite. The salt cake was washed with 20 ml of anhydrous hexanes twice. The 130 ml clear filtrate was stripped under vacuum (down to 1 torr) at up to room temperature till all low boilers were removed. The pot residue (6.70 g) was isolated as a clear colorless liquid product. The product was analyzed with GC-TCD, GC-MS and ¹H NMR. The product contained 76.2% aminochlorohydridodisilanes including 44.3% 1-diisopropylamino-1,2,2,2-tetrachlorodisilane ⁱPr₂N—SiClH—SiCl₃, 17.1% 1-diisoproylamino-1,1,2,2-tetrachlorodisilane HCl₂Si—SiCl₂—NPrⁱ₂ and 14.8% a bis(diisopropylamino)trichlorodisilane isomer HSi₂(NPrⁱ₂)₂Cl₃.

Example 5. Synthesis of 1,1-Bis(ethylmethylamino)-1-Chlorodisilane

A solution of 1.80 g (10.9 mmol) of 1,1,1-trichlorodisilane (3CDS) in 5 ml of hexane was added to a solution of 2.12 g (35.9 mmol) of ethylmethylamine and 3.63 g (35.9 mmol) of triethylamine in 90 ml of hexane in a 250 ml round bottom flask in 15 minutes at −5° C. After the addition, the reaction mixture (a slurry) was agitated for 30 minutes at room temperature −40° C. Then the reaction mixture was filtered to give a clear liquid. The volatile content in the liquid was removed under vacuum down to 1 torr. A clear liquid (0.96 g) was isolated. Estimated with GC-FID, the liquid contained about 30 wt % 1,1-bis(ethylmethylamino)-1-chlorodisilane. The structure of 1,1-bis(ethylmethylamino)-1-chlorodisilane was characterized with GC-MS and ¹H NMR.

Example 6. Synthesis of 1,1-Bis(diethylamino)-1-Chlorodisilane

A solution of 1.84 g (11.1 mmol) of 1,1,1-trichlorodisilane (3CDS) in 10 ml of hexane was added to a solution of 5.35 g (73.2 mmol) of diethylamine in 100 ml of hexane in a 250 ml round bottom flask in 15 minutes at −5° C. After the addition, the reaction mixture (a slurry) was agitated for 1.5 hours at room temperature. Then the reaction mixture was filtered to give a clear liquid. The volatile content in the liquid was removed under vacuum down to 1 torr. A clear liquid (1.35 g) was isolated. Estimated with GC-FID, the liquid contained about 59 wt % 1,1-bis(diethylamino)-1-chlorodisilane. The structure of 1,1-bis(diethylamino)-1-chlorodisilane was characterized with GC-MS and ¹H NMR.

Example 7: Forming a silicon nitride film using 1-diisopropylamino-1,1-dichlorodisilane (DPDCH3) with nitrogen or ammonia/nitrogen and PEALD.

Using a PEALD reactor and a small cylinder containing the DPDCH3 and in fluid communication with the PEALD reactor, the cylinder containing DPDCH3 was heated to 77° C. The PEALD reactor was purged with nitrogen (N₂), wherein the PEALD reactor contained a plurality of horizontally oriented and spaced apart silicon wafers heated at 350° C. (set-point). Then PEALD SiN film was grown with DPDCH3 in the following sequence: DPDCH3 dose, 1 to 10 sec/N₂ Purge, 30 sec/Plasma with N₂ or NH₃+N₂, 15 sec/N₂ Purge, 30 sec. The foregoing sequence of steps were repeated until a conformal silicon nitride film with a desired thickness was formed on the wafers.

The thickness and refractive index (at the wavelength of 632 nm) of silicon nitride film were characterized using spectroscopic ellipsometry (M-2000DI, J. A. Woollam). Ellipsometry data were collected from the wavelength range from 375 nm to 1690 nm and analyzed using Tauc-Lorentz oscillator model with software provided by J. A. Woollam. Wet etch rate tests of the thin films grown by PEALD processes were performed using 500:1 HF solution diluted in D.I. water at room temperature. The wet etch rate was calculated from the thickness difference before and after etching in diluted HF solution. The results are in the following table.

| | | | | | | | | WER of |
|---|---|---|---|---|---|---|---|---|
| | | | | | | | | PEALD SiN |
| | | Precursor | | | | | | film in |
| | | pulsing | | RF | | | RI @ | 500:1 HF |
| | | time | Plasma Gas | Power | Temp | GPC | 632.8 | solution |
| ID | Precursor | (sec) | (sccm) | (W) | (° C.) | (A/cycle) | nm | (nm/min) |
| T1 | DPDCH3 | 1 | N₂/NH₃ = 30/90 | 100 | 350 | 0.16 | 1.85 | 3.0 |
| T2 | DPDCH3 | 3 | N₂/NH₃ = 30/90 | 100 | 350 | 0.34 | 1.81 | 7.9 |
| T3 | DPDCH3 | 10 | N₂/NH₃ = 30/90 | 100 | 350 | 0.38 | 1.82 | 6.5 |
| T4 | DPDCH3 | 1 | N₂ = 50 | 100 | 350 | 0.19 | 1.93 | 1.7 |
| T5 | DPDCH3 | 3 | N₂ = 50 | 100 | 350 | 0.25 | 1.92 | 2.8 |
| T6 | DPDCH3 | 10 | N₂ = 50 | 100 | 350 | 0.38 | 1.91 | 4.0 |

Example 8 (prophetic): forming a silicon nitride film using the Silicon Precursor Compound and ammonia (NH₃) with LPCVD: using a LPCVD reactor and a bubbler containing the Silicon Precursor Compound and in fluid communication with the LPCVD reactor, heat the bubbler containing the Silicon Precursor Compound to 70° C. to increase vapor pressure thereof. Then flow He carrier gas through the bubbler to carry vapor of the Silicon Precursor Compound into the LPCVD reactor, wherein the LPCVD reactor contains vaporous ammonia and a plurality of vertically oriented and spaced apart silicon wafers heated to 500° C. so a conformal silicon nitride film is formed on the wafers.

Example 9 (prophetic): forming a silicon nitride film using the Silicon Precursor Compound with ammonia and PECVD: using a PECVD reactor and a bubbler in fluid communication with the PECVD reactor, heat the bubbler containing the Silicon Precursor Compound to 70° C. to increase vapor pressure thereof. Then flow He carrier gas through the bubbler to carry vapor of the Silicon Precursor Compound into the PECVD reactor, wherein the PECVD reactor has an ammonia-derived plasma and contains a plurality of horizontally oriented and spaced apart silicon wafers heated to 500° C. such that a conformal silicon nitride film is formed on the wafers.

Example 10 (prophetic): forming a silicon oxide film using the Silicon Precursor Compound with LPCVD: using a LPCVD reactor and a bubbler in fluid communication with the LPCVD reactor, heat the bubbler containing the Silicon Precursor Compound to 70° C. to increase vapor pressure thereof. Then flow He carrier gas through the bubbler to carry vapor of the Silicon Precursor Compound into the LPCVD reactor, wherein the LPCVD reactor has an oxygen atmosphere and contains a plurality of vertically oriented and spaced apart silicon wafers heated to 500° C. such that a conformal silicon oxide film is formed on the wafers.

Example 11 (prophetic): forming a silicon carbide film using the Silicon Precursor Compound with methane and PECVD: using a PECVD reactor and a bubbler in fluid communication with the PECVD reactor, heat the bubbler containing the Silicon Precursor Compound to 70° C. to increase vapor pressure thereof. Then flow He carrier gas through the bubbler to carry vapor of the Silicon Precursor Compound into the PECVD reactor, wherein the PECVD reactor has a methane-derived plasma and contains a plurality of horizontally oriented and spaced apart silicon wafers heated to 500° C. such that a conformal silicon carbide film is formed on the wafers.

The below claims are incorporated by reference here, and the terms “claim” and “claims” are replaced by the term “aspect” or “aspects,” respectively. Embodiments of the invention also include these resulting numbered aspects.

1. A compound which is a disilane and which comprises at least one chloro group, at least one dialkylamino group and at least one hydrido group.

2. The compound of claim 1, in which the compound has the formula:
(R¹R²N)ₐCl_{b}H_{c}SiSiH_{d}Clₑ(R¹R²N)_{f};
wherein each R¹ independently is H, (C₁-C₆)alkyl, (C₃-C₆)cycloalkyl, (C₂-C₆)alkenyl, (C₂-C₆)alkynyl, or phenyl; and each R² independently is (C₁-C₆)alkyl, (C₃-C₆)cycloalkyl, (C₂-C₆)alkenyl, (C₂-C₆)alkynyl, or phenyl; or R¹ and R² on a same or different nitrogen atom are bonded together to be —R^{1a}-R^{2a}— wherein —R^{1a}-R^{2a}— is (C₂-C₅)alkylene; and
wherein a, b, c, d, e and f are integers which range independently from zero to three; provided that at least one of a and f is not zero, at least one of b and e is not zero, and at least one of c and d is not zero.

3. The compound of claim 2, including one or more of limitations a), b), c) and d):
a) R¹ and R² independently are C₂-C₆ alkyl;
b) only one of a and f is one, and the other is zero;
c) b and e independently are zero, one or two;
d) b+e is from one to four.

4. The compound of claim 2, in which R¹ and R² independently are C₃-C₄ alkyl.

5. The compound of claim 1, in which the compound is [(CH₃)₂CH]₂NSiCl₂SiH₃, [(CH₃)₂CH]₂NSiH₂SiH₂Cl, [(CH₃CH₂)₂N]₂SiClSiH₃, [(CH₃CH₂)(CH₃)N]₂SiClSiH₃, HSiClN[CH(CH₃)₂]₂SiCl₃, HSiCl₂SiCl₂N[CH(CH₃)₂]₂, or HSi₂Cl₃[N(CH(CH₃)₂)₂]₂.

6. A method for producing a compound which is a disilane and which comprises at least one chloro group, at least one dialkylamino group and at least one hydrido group; said method comprising contacting a disilane having at least two chloro groups and at least one dialkylamino group with an aluminum hydride.

7. The method of claim 6, wherein the aluminum hydride comprises lithium aluminum hydride, lithium tri-tert-butoxyaluminum hydride, lithium tris[(3-ethyl-3-pentyl)oxy]aluminum hydride, sodium bis(2-methoxyethoxy)aluminium hydride, diisobutylaluminum hydride, or diethylaluminum hydride, or a combination of two or more of lithium aluminum hydride, lithium tri-tert-butoxyaluminum hydride, lithium tris[(3-ethyl-3-pentyl)oxy]aluminum hydride, sodium bis(2-methoxyethoxy)aluminium hydride, diisobutylaluminum hydride, and diethylaluminum hydride.

8. A method of forming a silicon-containing film on a substrate, said method comprising subjecting a vapor of a silicon precursor comprising the compound of claim 1 to deposition conditions in the presence of the substrate so as to form the silicon-containing film on the substrate.

9. The method of claim 8, including one or more of limitations e), f), g), h), and i):
e) wherein the silicon-containing film is an elemental silicon film, a silicon carbon film, a silicon nitrogen film, or a silicon oxygen film;
f) comprising subjecting a first vapor of the silicon precursor comprising the compound and a second vapor comprising helium or hydrogen to deposition conditions in the presence of the substrate so as to form the silicon-containing film on the substrate, wherein the silicon-containing film is an elemental silicon film;
g) comprising subjecting a first vapor of the silicon precursor comprising the compound and a second vapor of a carbon precursor comprising a hydrocarbon, hydrocarbylsilane or a combination of any two thereof to deposition conditions in the presence of the substrate so as to form the silicon-containing film on the substrate, wherein the silicon-containing film is a silicon carbon film;
h) comprising subjecting a first vapor of the silicon precursor comprising the compound and a second vapor of a nitrogen precursor comprising molecular nitrogen, ammonia, hydrazine, amine, or a combination of any two or three thereof to deposition conditions in the presence of the substrate so as to form the silicon-containing film on the substrate, wherein the silicon-containing film is a silicon nitrogen film;
i) comprising subjecting a first vapor of the silicon precursor comprising the compound and a second vapor of an oxygen precursor comprising molecular oxygen, ozone, nitric oxide, nitrogen dioxide, nitrous oxide, water, hydrogen peroxide, or a combination of any two or three thereof to deposition conditions in the presence of the substrate so as to form the silicon-containing film on the substrate, wherein the silicon-containing film is a silicon oxygen film.

10. The method of claim 8, wherein the substrate is heated and disposed in a deposition reactor that is configured for atomic layer deposition, the method comprising repeatedly feeding a first vapor of the silicon precursor comprising the compound, purging with an inert gas, feeding a second vapor into the deposition reactor, and purging with an inert gas so as to form the silicon-containing film on the heated substrate using atomic layer deposition, wherein the feeds may be the same or different.

11. The method of claim 8, wherein the substrate is heated and disposed in a deposition reactor that is configured for chemical vapor deposition, the method comprising feeding a first vapor of the silicon precursor comprising the compound and feeding a second vapor into the deposition reactor so as to form the silicon-containing film on the heated substrate using chemical vapor deposition, wherein the feeds may be the same or different.

12. The method of claim 10, wherein the vapor deposition conditions lack carbon and oxygen and the silicon nitrogen film comprises a silicon nitride film.

13. The method of claim 8, wherein the substrate is a semiconductor material.

14. A composition for forming a silicon nitrogen film, the composition comprising a silicon precursor comprising the compound of claim 1 and a nitrogen precursor.

15. The method of claim 11, wherein the vapor deposition conditions lack carbon and oxygen and the silicon nitrogen film comprises a silicon nitride film.
